(19) United States
(12) Patent Application Publication
(10) Pub. No.: US 2006/0096536 A1
(43) Pub. Date: May 11, 2006

(54) Pressure control system in a photovoltaic substrate deposition apparatus

(75) Inventor: John R. Tuttle, Mechanicville, NY (US)

Correspondence Address: HISCOCK & BARCLAY, LLP, 2000 HSBC PLAZA, ROCHESTER, NY, 14604-2404, US

(73) Assignee: DayStar Technologies, Inc.

(21) Appl. No.: 11/272,536

(22) Filed: Nov. 10, 2005

Related U.S. Application Data
(60) Provisional application No. 60/626,843, filed on Nov. 10, 2004.

(51) Int. Cl. C23C 16/00

(52) U.S. Cl. 118/719; 427/248.1

(57) ABSTRACT

This invention comprises an apparatus for the deposition of thin layers upon a substrate for the production of photovoltaic cells wherein the individual reaction chambers are separated from each other by low pressure isolation zones which prevent cross contamination of adjacent reaction chambers and control pressure levels in each reaction chamber while, at the same time, allowing the uninterrupted transfer of a substrate from one reaction chamber to the next without any mechanical obstruction.

### CROSS-REFERENCE TO RELATED APPLICATIONS

This application claims priority from U.S. Provisional Patent Application Ser. No. 60/626,843, filed Nov. 10, 2004.

### FIELD OF THE INVENTION

This invention relates to the production of photovoltaic cells and more specifically to a pressure control and isolation system for the uninterrupted transfer of a photovoltaic work piece from one reaction chamber to another.

### BACKGROUND OF THE INVENTION

Photovoltaic (PV) cells, modules and power systems offer clean, reliable, renewable energy to the World's expanding demand for electrical power. Unfortunately, product costs have not been sufficiently reduced to open up the critical markets in the developing world where electricity demand is driving them to polluting, non-renewable sources such as coal and oil. With the population expanding, and per-capita energy consumption going up, the world is heading towards an irreconcilable future where energy demand and supply irreversibly diverge.

PV cells offer an alternative to non-renewable energy sources. However, although relatively efficient PV cells can be manufactured in the laboratory, it has proven difficult to enlarge the process to a commercial scale with consistent repeatability and efficiency critical for commercial viability. The lack of an efficient thin-film manufacturing process has contributed to the failure of PV cells to effectively replace alternate energy sources in the market.

Currently, cells are manufactured using a multi-step batch process wherein each product piece is transferred between reaction steps and such transfer is bulky and requires reaction in chambers to be cycled. A typical process consists of a series of individual batch processing chambers each specifically designed for the formation of various layers in the cell. One drawback to this process is that the substrate is transferred from vacuum to air and back to vacuum several times. An alternate system uses a series of individual batch processing chambers coupled with a roll-to-roll continuous process for each chamber. The major drawback in this process is the discontinuity of the system and the need to break vacuum.

One aspect of a PV cell manufacturing apparatus must be that a product piece, or substrate, will be able to travel from one reaction chamber to another reaction chamber without the loss of vacuum. Also, while enabling the substrate to travel between two reaction chambers, the apparatus must not allow reactants in one reaction chamber to contaminate another reaction chamber. This concern is not trivial because the chemical composition of a p-type absorber is so similar to the chemical composition to the n-type junction in a PV cell, that even a very low level of cross contamination between two reaction chambers could have very significant effects of cell performance. Therefore, a manufacturing apparatus with the ability to prevent cross contamination between two reaction chambers is required.

Another aspect of a PV manufacturing apparatus is the need to closely control temperature and pressure within a given reaction chamber. Often, the formation of a given layer depends upon temperature and pressure within that reaction chamber. Therefore a system that can regulate the pressure within a reaction chamber is required.

U.S. Pat. No. 5,470,784 issued to Coleman on Nov. 28, 1995, discloses an apparatus for coating a substrate with semiconductor material for a PV cell with a number of deposition chambers divided by a series of “ports” which are at a lower pressure than the deposition compartments. However, this patent does not contemplate the use of a pure gas in concert with a differential pumping arrangement to control the pressure in a reaction chamber. Furthermore, this invention does not teach the construction of an orifice that will restrict flow of gas from a reaction chamber to an isolation zone. Nor does Coleman teach a continuous manufacturing process.

U.S. Pat. No. 5,343,012 to Hardy discloses a method for controlling the temperature of a substrate upon which a thin film structure is to be fabricated. However, this invention does not disclose the transporting of a substrate from one deposition chamber to a second deposition chamber.

U.S. Pat. No. 6,554,950 to van Mast discloses a method and apparatus for removal of surface contaminants from substrates in vacuum applications. However, this invention does not disclose either the use of differential pumping to control pressure in a reaction chamber, nor does it disclose the use of differential pumping to transfer a substrate from one reaction chamber to a second reaction chamber.

U.S. Pat. No. 6,270,861 issued to Mashburn on Aug. 7, 2001 discloses an apparatus for forming thin films in a deposition chamber where differential pumping is used to prevent the interaction of two distinct atmospheres. However, this invention does not contemplate the concept of a vacuum barrier existing between two reaction chambers each of a pressure higher than the barrier.

U.S. Pat. No. 5,849,162 to Bartolomei discloses a device and process for a more effective sputtering process. While the apparatus utilizes differential pumping and a plurality of stations wherein a substrate may have a layer deposited upon it, the invention does not use isolation zones necessary to form reaction chambers each of independent temperature and pressure.

U.S. Pat. No. 4,851,095 to Scobey discloses a deposition apparatus for a continuous substrate through a plurality of reaction stations. However, the invention does not contemplate the need for different pressures and temperatures for each reaction chamber nor a vacuum isolation zone between them.

### SUMMARY OF THE INVENTION

This invention is an apparatus for the production of photovoltaic (PV) cells with at least one differential pumping mechanism that provides a vacuum isolation zone in communication with at least one reaction chamber and where the reaction chamber contains a mechanism for controlling the influx of a pure gas to the reaction chamber. In one embodiment, the isolation zone is placed between two sequential reaction chambers, but this is not a necessary condition of the invention. Acting in concert with the differential pumping mechanism is an instrument for controlling the influx of a pure gas into the connected reaction chamber thereby maintaining a near vacuum in that reaction chamber, but the pressure in the isolation zone is always lower than the reaction chamber. Associated with the apparatus is an orifice at the isolation zone/reaction chamber interface that is sufficiently large enough to allow the substrate to pass from chamber to chamber without interrupting the process while, at the same time, minimize the flow of gas from the reaction chamber into the isolation zone. These orifices are roughly the same size as the pallet that proceeds through them, but slightly larger to account for imprecision of the pallet placement and potential thermal expansion.

This invention further comprises a method for pressure control in a plurality of independent deposition and reaction chambers comprising controlling the influx of a gas into the reaction chambers, feeding a substrate through orifices at the inlet and outlet of the reaction chambers, establishing an isolation zone of lower pressure adjacent to and in communication with the reaction chambers and removing the gas exiting the reaction chamber to prevent cross contamination into an adjacent reaction chamber.

The advantage of this apparatus is the isolation of the reaction chambers to prevent cross contamination while, at the same time, it allows a substrate to pass uninterrupted from one chamber to another. In one embodiment, a pallet or number of pallets may exit one reaction chamber and be temporary situated in an isolation zone while minimizing adverse effects to the substrate and then enter the next subsequent reaction chamber at some later time. In another embodiment, the pallets may be organized in a train like fashion such that all reaction chambers are operational simultaneously on different pallets. This invention also makes possible a continuous, or “roll-to-roll”, substrate design moving continuously through a series of reaction chambers, each separated by a pressure controlled isolation zone. Although many references disclose the concept of a continuous substrate, the current invention enables the photovoltaic manufacturing process to be truly continuous.

In the operation of one embodiment, a differential pump, or a series of differential pumps, is attached to the isolation zone. This pump may continuously run or be cycled to maintain a vacuum, while the addition of inert gas to the reaction chamber gives that chamber some pressure greater than a complete vacuum as necessary for the reaction. In one embodiment, the pressure and temperature may be monitored by an array of sensors and analyzed by a controlling device, such as a computer, which may autonomously control the environmental characteristics of the reaction chambers.

One object of this invention is to provide a pressure isolation apparatus for allowing a substrate to pass through a series of reaction chambers, each of which deposits a thin chemical layer for the production of a photovoltaic cell while substantially maintaining the deposition and/or reaction conditions necessary in each reaction chamber.

Another object of this invention enables the transfer a substrate from one reaction chamber to the next subsequent chamber, or to the outside atmosphere, without subjecting the substrate to large temperature and pressure changes during the transfer.

A third object of the present invention is to transfer a substrate from a reaction chamber to the next subsequent reaction chamber without allowing cross contamination between the two reaction chambers.

### BRIEF DESCRIPTION OF THE DRAWINGS

The above-mentioned and other features and advantages of this invention, and the manner of attaining them, will become apparent and be better understood by reference to the following description of several embodiments of the invention in conjunction with the accompanying drawings, wherein:

FIG. 1 is a schematic diagram of a single isolation zone between two reaction chambers;

FIG. 1a is a diagram of a vacuum pump apparatus with an associated collection facility;

FIG. 2 is a perspective view of one potential embodiment showing the possible shape of the isolation zone;

FIG. 3 is a schematic diagram of a single isolation zone with the vacuum pump apparatus installed internally in the isolation zone;

FIG. 4 is schematic diagram of a single isolation zone connected to a single reaction chamber and a removal area for completed substrates.

Corresponding reference characters indicate corresponding parts throughout the several views. The examples set out herein illustrate several embodiments of the invention but should not be construed as limiting the scope of the invention in any manner.

### DETAILED DESCRIPTION

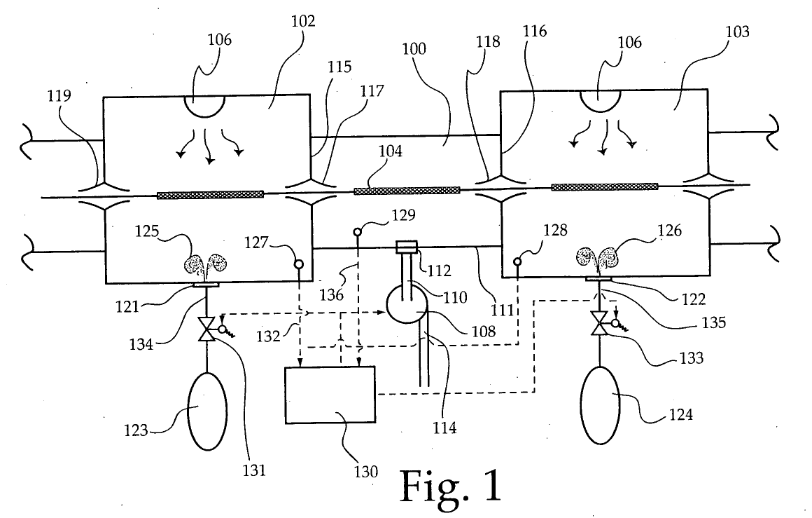

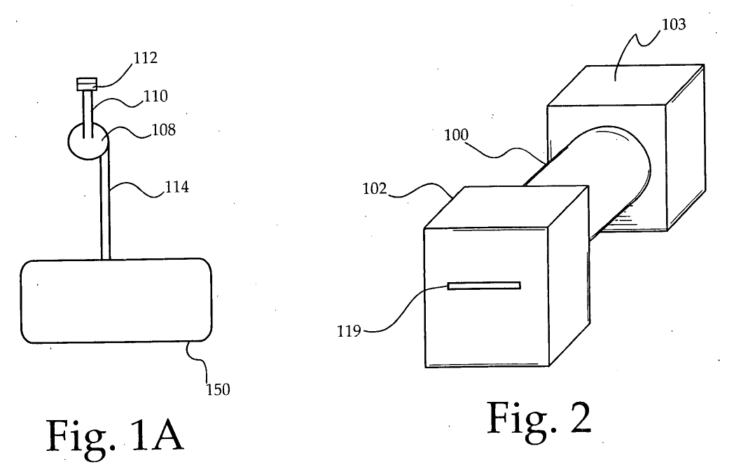

An embodiment of the current invention is depicted in FIG. 1 and comprises an enclosed isolation zone 100 that is attached to at least one reaction chamber 102 but, in most cases, the enclosed isolation zone 100 is attached between two reaction chambers 102. The physical shape of the isolation zone 100 may be any shape, such as cube or rectangular, and may be determined by the size of the pallet, work piece, or other substrate transportation device 104. Obviously, the shape of the isolation zone 100 may be driven by optimizing performance in a vacuum, therefore a cylindrical, as depicted in FIG. 2, or spherical shape may be necessary to support drawing a vacuum in the area of 10⁻⁷ torr. The size of the enclosed isolation zone 100 may also be determined by the reaction requirements of the photovoltaic production process. Factors which may influence the length of the isolation zone 100, for example, may be issues such as internal pressure of adjacent reaction chambers, residence time of the work piece 104 in the reaction chamber 102 and the sensitivity of the work process to cross-contamination between reaction chambers.

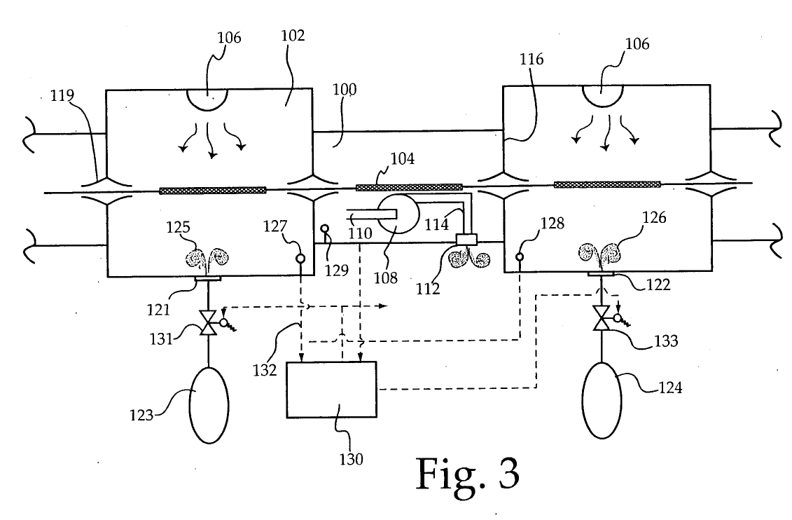

On at least one end of the isolation zone is a reaction chamber 102, which includes an apparatus 106 for the deposition of a chemical or alloy on a substrate. Common methods for the deposition include evaporation, sputtering and other techniques known to those skilled in the art. Regardless of the deposition method, it is considered likely that the pressures in the reaction chambers will be exceedingly low, typically in the range of 10⁻⁶-10⁻³ torr. In order to maintain an isolation zone 100 that will prevent cross contamination between adjacent reaction chambers 102, the isolation zone 100 is accompanied by a pump 108 whereby the suction side 110 of this pump is attached to the isolation zone wall 111 by a connecting device 112, or may be permanently attached to the isolation zone wall 111 which will enable the pressure of the isolation zone to be continuously less than the pressures of the adjacent reaction chambers 102, approximately 10⁻⁷ torr. In another embodiment, as depicted in FIG. 3 the pump 108 may be installed internally within the isolation zone 100 with the pump discharge 114 being connected to the isolation zone wall 111 from the inside. It is also contemplated that a number of pumps 108 in series may be necessary to achieve sufficient vacuum. Nothing in this invention precludes the use of a single differential pump for a plurality of isolation zones; however this may likely cause a different ΔP across each reaction chamber/isolation zone interface 116, which may be undesirable.

In order to enable a substrate 104 to pass from a reaction chamber 102, through an isolation zone 100 and into the next reaction chamber 103, an orifice is placed on both inlet 117 and outlet 118 of the isolation zone 100 at the reaction chamber/isolation zone interface 115, 116. One skilled in the art would easily observe that, with the presence of the orifices 117, 118, that if left alone, the differential pump 108 would evacuate both the isolation zone 100 as well as the reaction chambers 102, 103 to an equally low vacuum. As it is important for the pressure in the reaction chambers 102, 103 to be greater than the pressure of the isolation zone 100 in order to prevent cross contamination between two reaction chambers, the reaction chambers 102, 103 must be “pressurized” by an external pressure source to counter the vacuuming effect of the pump 108. In one embodiment, this is achieved through the introduction of a pure gas 125, 126, such as argon, nitrogen, or oxygen, into the reaction chambers 102, 103 via a gas inlet 134, 135.

These inlets 134, 135 may be attached to the reaction chamber walls via a connecting device 121, 122 similar to the device connecting the suction side of the vacuum pump to the isolation zone wall 112. FIG. 1 displays a pure gas storage tank 123, 124 attached to each gas inlet 134, 135. This embodiment reflects the possibility that the processes occurring in two different reaction chambers may require the pure gas in one reaction chamber 125 to be different from the pure gas 126 in another reaction chamber for optimal photovoltaic results. However, this invention does not preclude the use of a single pure gas tank to be used for all reaction chambers. In addition, other gases may also be used for pressure control, but this may depend upon factors such as the process in the reaction chamber, the potential for contamination of the substrate and the required pressure and temperature of the process. Viewing FIG. 1a, in the case where the pure gas may be in short supply, or the release of the gas may be an environmental contaminant; a collection tank 150 may be attached to the outlet of the pump 114 to collect the pure gas for later use or proper disposal.

In order to maintain a pressure in the reaction chamber 102, 103 that is greater than the isolation zone 100, the orifice 117, 118 must be able to limit the loss of pure gas 125, 126 in the reaction chamber 102, 103 to the isolation zone 100 due to the differential pressure across the isolation zone/reaction chamber boundaries 115, 116. The orifice must therefore be limited in size and configuration to limit this loss. As FIG. 1 represents only a segment of what may be a large deposition apparatus, an orifice 119 is also attached to the inlet and outlet of each reaction chamber. Preferably, the orifice is only marginally larger than the substrate 104 itself.

In such an embodiment, the operation of the orifice in a “roll-to-roll” process would be most effective since the substrate itself would continuously inhibit the outward flow of gas from the reaction chamber to the isolation zone. In another embodiment, specifically in the case of individual “pallet” substrates, the orifice 117, 118 is opened only when the pallet 104 enters or leaves a reaction chamber to totally prevent the loss of gas and subsequent depressurization.

In this embodiment, temperature and pressure sensors 127, 128 are placed in the reaction chambers and are in electrical communication, as represented by dashed line 132 with a controlling device 130, which may be a computer, and continuously monitor reaction chamber temperature and pressure. The controlling 130 device compares these values with the temperature and pressure of the isolation zone 100, which is also measured by a sensor 129 that is in electrical communication, as represented by dashed line 136 with the controlling device 130. To maintain the proper ΔP across the reaction chamber/isolation zone interface, the controlling device 130 may control either the flow rate of the pure gas 125, 126 into the reaction chambers through the electrical control of solenoid or throttle valves 131, 133 which are located between the pure gas inlets 134, 135 and the pure gas storage tanks 123, 124. In another embodiment, ΔP may be controlled through the control of the vacuum pump 108 instead of pure gas flow rate, or some combination of pump and pure gas flow rate control.

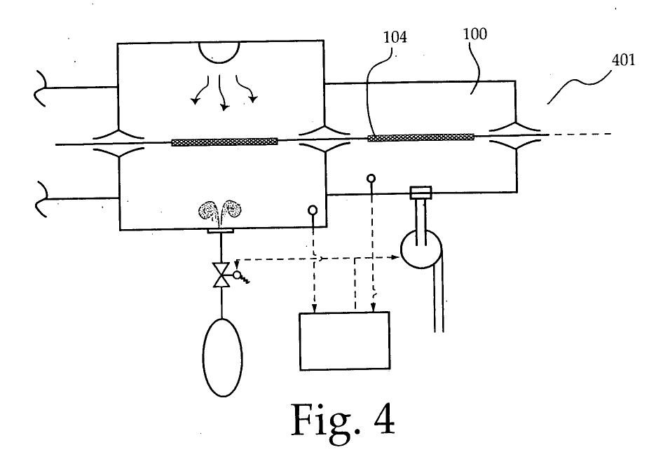

As previously mentioned, isolation zones need not solely exist between two reaction chambers. In another embodiment, isolation zones may be only in communication with one reaction chamber in order to prevent contamination between a reaction chamber and the outside atmosphere as depicted in FIG. 4. In this embodiment, an isolation zone 100 serves as a terminus where the substrate 104 is either complete or must be transferred to another apparatus for further development. As seen in FIG. 4, an access point 401 is provided for substrate 104 removal. An isolation chamber such as this would be ideal for prevention of impurities in the air reaching into the reaction chamber, which will likely be at or near vacuum levels. However, the ΔP across this isolation zone is much more significant than the ΔP across any reaction chamber/isolation zone interface.

Under normal conditions and using deposition methods known to those skilled in the art, the ΔP between the atmosphere and an isolation zone may be 1000 times greater than the ΔP between an isolation zone and a reaction chamber. Because of this large ΔP, a simple access point 401 between the isolation zone and the outside atmosphere may be insufficient. Therefore, the access point may not be continuously open like the other orifices.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

Therefore, it is intended that the invention not be limited to the particular embodiments disclosed as the best mode contemplated for carrying out this invention, but that the invention will include all embodiments falling within the scope and spirit of the appended claims.

What is claimed is:

1. An apparatus for the production of photovoltaic devices comprising:
a. at least one differential pumping means that provides a vacuum isolation zone or zones in communication with at least one reaction chamber; and
b. said reaction chamber contains a mechanism for controlling the influx of a pure gas to the reaction chamber.

2. The apparatus of claim 1, wherein the pressure in said isolation zones is lower than said reaction chamber.

3. The apparatus of claim 2, wherein said reaction chamber provides deposition conducted at a pressure of 2-10 E⁻³ torr and said pumping means operates at 1 E⁻⁴ torr.

4. The apparatus of claim 1, wherein said gas is removed from said reaction chamber via said isolation means.

5. The apparatus of claim 4, wherein said gases are removed from said reaction chambers via said isolation means and directed to a collection facility.

6. The apparatus of claim 4, wherein an orifice is provided at the junction between one said reaction chamber and one said isolation zone through which a substrate may pass.

7. The apparatus of claim 6, wherein said orifice is of similar thickness to the substrate to minimize gas flow from said reaction chamber to said isolation zone.

8. The apparatus of claim 6, wherein said orifice may be cycled shut.

9. The apparatus of claim 1, wherein said reaction chambers contain a monitoring device to scan temperature and pressure of said reaction chambers.

10. The apparatus of claim 9, wherein said monitoring mechanism may control the input rate of said pure gas.

11. A method for pressure control in a plurality of independent deposition and reaction chambers used to produce a photovoltaic device comprising:
a. controlling the influx of gas into said CGS reaction chambers;
b. feeding a substrate through orifices at the inlet and outlet of said reaction chambers;
c. establishing an isolation zone of lower pressure adjacent to and in communication with said inlet and outlet of said reaction chambers; and
d. removing said pure gas exiting said reaction chamber into said isolation zone and maintaining the pressure in said isolation zone at 1 E⁻⁴ torr.

12. The method of claim 11, wherein said substrate is a continuous layer that is able to be fed continuously through said reaction chamber.

13. The method of claim 12, wherein said substrate is affixed to a pallet wherein one or more said pallets are placed in said reaction chamber.

14. The method of claim 13, wherein the said orifices may be shut after the insertion of said pallets.

15. The method of claim 11, wherein said gases exiting said reaction chamber are removed via said isolation zones.

16. The method of claim 15, wherein said gases are transferred to a collection facility.

17. The method of claim 11, wherein said isolation zone is a junction between the outlet of one said isolation zone and the inlet of an adjacent said isolation zone.
